(19) United States
(12) Patent Application Publication
(10) Pub. No.: US 2023/0383181 A1
(43) Pub. Date: Nov. 30, 2023

(54) PHOSPHOR CERAMIC, LIGHT-EMITTING DEVICE AND MANUFACTURING METHODS THEREFOR

(71) Applicant: NICHIA CORPORATION, Anan-shi (JP)

(72) Inventor: Takeshi SADAMOCHI, Tokushima-shi (JP)

(73) Assignee: NICHIA CORPORATION, Anan-shi (JP)

(21) Appl. No.: 18/325,543

(22) Filed: May 30, 2023

(30) Foreign Application Priority Data
May 30, 2022 (JP) 2022-087607

(51) Int. Cl. C09K 11/77; H01L 33/64

(52) U.S. Cl. CPC C09K 11/77066; H01L 33/641; H01L 2933/0075; H01L 33/32

(57) ABSTRACT

A method for manufacturing a phosphor ceramic, the method including preparing a precursor including aluminum nitride, and forming the phosphor ceramic by bringing the precursor into contact with a gas containing manganese.

### CROSS-REFERENCE TO RELATED APPLICATIONS

The present application claims priority under 35 U.S.C. § 119 to Japanese Patent Application No. 2022-087607, filed May 30, 2022, the contents of which are hereby incorporated by reference in their entirety.

### BACKGROUND

### 1. Technical Field

The present disclosure relates to a phosphor ceramic, a light-emitting device and a method for manufacturing the phosphor ceramic and light-emitting device.

### 2. Description of Related Art

Nitride phosphors are attracting attention as materials that exhibit excellent physical and chemical properties. Japanese Patent Publication No. S62-167260 discloses a method for manufacturing a luminescent sintered body by mixing aluminum nitride and a compound containing an element serving as a light emission center and a sintering aid, and firing the mixture thereof. WANG, Xiao-Jun et al., Dalton Transactions, 2014, 43, pp. 6120-6127 discloses a phosphor powder formed by firing a mixed powder of aluminum nitride and manganese carbonate to activate divalent manganese by the aluminum nitride.

### SUMMARY

A demand exists for a phosphor ceramic with improved thermal conductivity.

Thus, an object of one aspect of the present disclosure is to provide a phosphor ceramic having high thermal conductivity and a method for manufacturing the phosphor ceramic.

A first aspect provides a method for manufacturing a phosphor ceramic, the method including: preparing a precursor comprising aluminum nitride, e.g., as a base material; and forming the phosphor ceramic by bringing the precursor into contact with a gas containing manganese.

A second aspect provides a method for manufacturing a light-emitting device, the method including: preparing the phosphor ceramic; preparing an excitation light source; and arranging the phosphor ceramic at a position irradiated by light emitted by the excitation light source.

A third aspect provides a phosphor ceramic containing aluminum nitride, yttrium, and manganese, wherein a content of oxygen in the phosphor ceramic is less than 2.4 mass %.

A fourth aspect provides a light-emitting device including: an excitation light source; and the phosphor ceramic arranged at a position irradiated with light emitted by the excitation light source.

According to one aspect of the present disclosure, a phosphor ceramic having high thermal conductivity and a method for manufacturing the phosphor ceramic can be provided.

### BRIEF DESCRIPTION OF THE DRAWINGS

A more complete appreciation of embodiments of the disclosure and many of the attendant advantages thereof will be readily obtained by reference to the following detailed description when considered in connection with the accompanying drawings.

FIG. 1 is a flowchart illustrating an example of a method for manufacturing a phosphor ceramic.

FIG. 2 is a flowchart illustrating an example of a method for manufacturing a phosphor ceramic, the method including a method for manufacturing a precursor.

FIG. 3 is a flowchart illustrating another example of a method for manufacturing a phosphor ceramic, the method including a method for manufacturing a precursor.

FIG. 4 is a cross-sectional view illustrating an example of a light-emitting device containing a phosphor ceramic.

FIG. 5 is a graph of X-ray diffraction patterns of a phosphor ceramic according to Example 11 and of AlN, MnO₂, and Y₂O₃ registered in the Inorganic Crystal Structure Database.

FIG. 6 is a graph of an excitation spectrum resulting from the phosphor ceramic according to Example 11.

FIG. 7 is a graph of an emission spectrum resulting from the phosphor ceramic according to Example 11.

FIG. 8A is a cross-sectional SEM image of the phosphor ceramic according to Example 1.

FIG. 8B is a cross-sectional SEM image of the phosphor ceramic according to Example 11.

### DESCRIPTION OF EMBODIMENTS

The word “step” herein includes not only an independent step, but also a step that cannot be clearly distinguished from another step provided that the anticipated purpose of the step is achieved. If a plurality of substances applicable to a single component in a composition is present, the content of the single component in the composition means the total amount of the plurality of substances present in the single composition, unless otherwise specified. Furthermore, with respect to an upper limit and a lower limit of numerical ranges described herein, the numerical values exemplified as the numerical range can be freely selected and combined. Embodiments of the present disclosure will be described below in detail. However, the embodiments described below are merely examples of a phosphor ceramic and a method for manufacturing the phosphor ceramic to embody the technical concept of the present disclosure, and the present disclosure is not limited to the below-described phosphor ceramic or method for manufacturing the phosphor ceramic.

In the present specification, the term ceramic refers to an aggregate of a material in which a plurality of powders is bonded by sintering. Therefore, for example, a material that has maintained the state of the raw material powders, as with aluminum nitride powder, is not included in the term ceramic. As used herein, ppm refers to parts per million by mass as determined by (mass)/(mass).

Hereinafter, a phosphor ceramic, a method for manufacturing the phosphor ceramic, a light-emitting device, and a method for manufacturing the light-emitting device according to the present disclosure will be described based on embodiments. However, the embodiments presented below are examples for embodying a technical concept of the present disclosure, and the present disclosure is not limited to the configurations described below.

Phosphor Ceramic

A phosphor ceramic of the present embodiment contains aluminum nitride, yttrium, and manganese. The oxygen content of the phosphor ceramic of the present embodiment is less than 2.4 mass %. As will be described later, aluminum nitride is a base material of the phosphor ceramic. Accordingly, the phosphor ceramic may also be referred to as an aluminum nitride phosphor ceramic.

According to the present embodiment, a phosphor ceramic having high thermal conductivity can be provided.

Aluminum Nitride

The phosphor ceramic includes aluminum nitride. Aluminum nitride is a base material of the phosphor ceramic. In the present specification, the term “base material” refers to a material accounting for, in terms of volume, for example, from 90% to less than 100%, and preferably from 95% to 99.9% in relation to the total amount of a target material. Here, the aluminum nitride accounts for, in terms of volume, for example, a range from 90% to 99.9%, and preferably a range from 95% to 99.9% in relation to the total amount of the phosphor ceramic. Aluminum nitride, which serves as the base material, forms an aluminum nitride crystal phase. Hereinafter, the aluminum nitride crystal phase is also simply referred to as a crystal phase. The crystal phase is an aggregate of a plurality of aluminum nitride particles bonded together. The aluminum nitride particles are also simply referred to as AlN particles below. The AlN particles constituting the crystal phase include, for example, particles having a size in a range from 8 μm to 30 μm. In addition, the AlN particles constituting the crystal phase may include, for example, particles having a size in a range from 10 μm to 20 μm. In a case in which, for example, oxygen contained in the phosphor ceramic is sufficiently discharged, the crystal phase containing AlN particles of such a size can be contained in the phosphor ceramic as a crystal phase having high purity. The thermal conductivity of the phosphor ceramic can be improved by including AlN particles having such a particle diameter. Note that the size of the AlN particles is not limited to the above range. When the crystal phase is formed using high-purity AlN particles, the thermal conductivity of the phosphor ceramic can be improved even if the size of the AlN particles is relatively small. For example, the size of the AlN particles may be in a range from 1 μm to less than 8 μm. The size of the AlN particles can be determined, for example, by examining the size of the AlN particles in an area in a cross-sectional SEM image observed at a magnification of 1000 times. The area is, for example, an area of 127 μm×88 μm. A straight line may be drawn on the captured image, and the length from one grain boundary to another grain boundary of the AlN particles overlapping the straight line may be measured. The average value of the sizes of the AlN particles measured by the above-described method may be, for example, in a range from 1 μm to 30 μm.

Manganese

The phosphor ceramic contains manganese. The content of manganese in the phosphor ceramic is, for example, 50 ppm or less. Through this, the crystal phase of the phosphor ceramic is doped with manganese, and the phosphor ceramic can function as a phosphor. That is, aluminum nitride doped with manganese can emit light upon the reception of light of a predetermined wavelength emitted from an excitation light source. The content of manganese in the phosphor ceramic is preferably 30 ppm or less, more preferably 10 ppm or less, and even more preferably 5 ppm or less. As a result, the phosphor ceramic can both emit light and have high thermal conductivity. The content of manganese in the phosphor ceramic may be, for example, 1 ppm or more. The specific amount of manganese (Mn) in the phosphor ceramic can be estimated by trace analysis using a high-frequency inductively coupled plasma (ICP) emission spectrometer (for example, the Avio 500 available from PerkinElmer Inc.).

Yttrium

The phosphor ceramic may contain at least one type of rare earth element. For example, the phosphor ceramic may contain yttrium. The content of yttrium may be, for example, 5 mass % or less, 1 mass % or less, 0.5 mass % or less, 0.3 mass % or less, or 0.1 mass % or less. Setting the content of yttrium to, for example, 0.5 mass % or less, 0.3 mass % or less, or 0.1 mass % or less reduces the grain boundary phase connecting the crystal phases, and improves the transmittance of light in the phosphor ceramic. In addition, the distance between crystal phases can be shortened, and therefore the thermal conductivity of the phosphor ceramic can be improved. When the phosphor ceramic is produced using a sintering aid, the rare earth element contained in the sintering aid can be contained in the phosphor ceramic.

Oxygen

The phosphor ceramic may contain oxygen. The content of oxygen in the phosphor ceramic may be, for example, less than 2.4 mass %. Setting the content of oxygen to this level can improve the thermal conductivity of the phosphor ceramic. The content of oxygen in the phosphor ceramic is preferably 1 mass % or less, 0.5 mass % or less, 0.3 mass % or less, or 0.1 mass % or less. When the oxygen content is set to such an amount, the grain boundary phase can be reduced, and thus the light transmittance of the phosphor ceramic can be improved. In addition, the distance between crystal phases can be shortened, and therefore the thermal conductivity of the phosphor ceramic can be improved. The oxygen content in the phosphor ceramic can be measured using an oxygen/nitrogen analyzer (for example, the EMGA-820, available from Horiba, Ltd.). Note that the oxygen content in the phosphor ceramic may be equal to or less than a detection limit value of the oxygen/nitrogen analyzer and may be undetectable.

Other Metal Element

The phosphor ceramic may contain a metal element other than aluminum, yttrium, and manganese. The content of the metal element other than aluminum, yttrium, and manganese is, for example, 1 mass % or less, 0.5 mass % or less, or 0.1 mass % or less. When the content of the metal element other than aluminum, yttrium, and manganese is less than a predetermined content, coloring of the phosphor ceramic, a decrease in thermal conductivity, unnecessary light absorption, and the like can be reduced.

Grain Boundary Phase

The phosphor ceramic may include a grain boundary phase connecting the crystal phases. The grain boundary phase may include an oxide containing yttrium. The grain boundary phase can be reduced by reducing the contents of yttrium and oxygen as described above. The content of yttrium can be determined by cutting the aluminum nitride phosphor ceramic so as to expose a cross section thereof, and then analyzing a specific location within the cross section using, for example, an electron probe microanalyzer (EPMA), or a scanning electron microscope (SEM) and energy dispersive X-ray analysis (EDX). The yttrium content can be measured by using, as the EPMA, a field emission electron probe microanalyzer (for example, model number JXA-8500F, available from JEOL Ltd.). The yttrium content can also be measured by using, for the SEM and EDX, an SEM-EDX apparatus (for example, model number SU8230, available from Shimadzu Corporation, and a silicon drift detector, available from Horiba, Ltd.). For example, the content of yttrium present in the grain boundary phase can be measured by selecting any three to five locations in the grain boundary phase in a cross section of the aluminum nitride phosphor ceramic, detecting the content of yttrium in the grain boundary phase at the selected locations, and averaging the values thereof

Thermal Conductivity

The phosphor ceramic has excellent heat dissipation properties. This is because the thermal conductivity of the phosphor ceramic can be a relatively high value because the base material is aluminum nitride. The thermal conductivity of the phosphor ceramic is, for example, in a range from 150 W/(m·K) to 260 W/(m·K), preferably in a range from 200 W/(m·K) to 260 W/(m·K), more preferably in a range from 210 W/(m·K) to 260 W/(m·K), and particularly preferably in a range from 220 W/(m·K) to 260 W/(m·K). The thermal conductivity can be determined by the product of the thermal diffusivity a (m²/s), the specific heat capacity Cp (J/(kg·K)), and the apparent density (kg/m³). In the present specification, a value of 0.72 J/(kg·K), which is the specific heat capacity of aluminum nitride, is used as the value of the specific heat capacity Cp.

Thermal Diffusivity

The phosphor ceramic may have a thermal diffusivity measured by the laser flash method at 25° C. that is, for example, in a range of 60 mm²/s to 136.3 mm²/s. The value of 136.3 mm²/s represents the thermal diffusivity of single-crystal aluminum nitride. In addition, the thermal diffusivity of the phosphor ceramic may be in a range of 68 mm²/s to 136.3 mm²/s, preferably in a range of 80 mm²/s to 136.3 mm²/s, and may be in a range from 85 m²/s to 136.3 mm²/s, a range of 90 mm²/s to 130 mm²/s, a range of 95 mm²/s to 125 mm²/s, or a range of 100 mm²/s to 120 mm²/s. The thermal diffusivity of a 10 mm (length)×10 mm (width)×2 mm (thickness) sample can be measured at 25° C. by the laser flash method using, for example, a laser flash analyzer (for example, the LFA 447 or the LFA 467 available from Netzsch GmbH).

Apparent Density

The apparent density of the phosphor ceramic may be, for example, in a range of 2.5 g/cm 3 to 3.5 g/cm 3, a range of 3.0 g/cm 3 to 3.5 g/cm 3, a range of 3.1 g/cm 3 to 3.5 g/cm 3, or a range of 3.2 g/cm 3 to 3.5 g/cm 3. The value of 3.5 g/cm 3 is the theoretical apparent density of the phosphor ceramic. The apparent density can be calculated by dividing the mass of the phosphor ceramic by the volume measured by the Archimedes method.

Excitation Spectrum

The excitation spectrum of the phosphor ceramic may have a peak in a wavelength range of 230 nm to 250 nm. In addition, the excitation spectrum may have a shoulder structure in a range of 260 nm to 300 nm. The excitation spectrum may also be such that the absolute value of the rate of change of the spectral intensity in a range of 260 nm to 280 nm is smaller than the absolute value of the rate of change of the spectral intensity in a range of 240 nm to 260 nm.

Emission Spectrum

The phosphor ceramic emits light upon receiving excitation light. The emission spectrum of the phosphor ceramic has a peak in a range from 590 nm to 620 nm. The half width at half maximum (HWHM) in the light emission spectrum is 50 nm or less, preferably 40 nm or less, and more preferably 25 nm or less. In addition, the phosphor ceramic has an afterglow characteristic and can generate afterglow for several tens of seconds to about one minute even after the irradiation of the excitation light has ended. In addition, the emission intensity of the phosphor ceramic can be increased, for example, by being exposed to excitation light for a long period of time.

A phosphor ceramic was described above, but the phosphor ceramic may also have the following configuration, for example. Descriptions of overlapping details are omitted. The phosphor ceramic may be a phosphor ceramic containing aluminum nitride and manganese, wherein the content of the manganese is in a range from 1 ppm to 50 ppm, and the thermal diffusivity of the phosphor ceramic measured by the laser flash method at 25° C. is 60 mm²/s or higher. This enables forming of a phosphor ceramic having high thermal conductivity.

Manufacturing Method

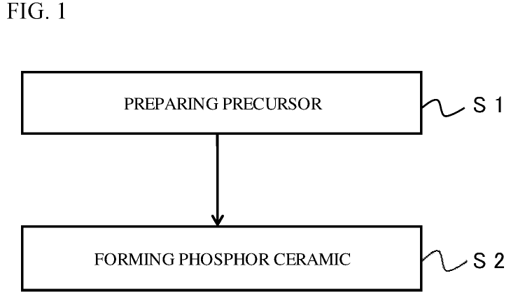

The method for manufacturing the phosphor ceramic includes preparing a precursor in which the base material is aluminum nitride, and bringing the precursor into contact with a gas containing manganese to form a phosphor ceramic. FIG. 1 is a flowchart illustrating an example of a method for manufacturing a phosphor ceramic. The method for manufacturing the phosphor ceramic includes a step S1 of preparing a precursor and a step S2 of forming the phosphor ceramic.

According to the method of the present embodiment for manufacturing a phosphor ceramic, a phosphor ceramic having high thermal conductivity can be formed.

Step S1 of Preparing a Precursor

This step is a step of preparing a precursor of a phosphor ceramic. The precursor is a molded body containing aluminum nitride or a sintered body containing aluminum nitride. The precursor uses aluminum nitride as a base material. The aluminum nitride serving as the base material accounts for, in terms of volume for example, a range from 90% to less than 100%, and preferably a range from 95% to 99.9% in relation to the total amount of the precursor. As the precursor, a commercially available product may be used, or the precursor may be manufactured by the method described below.

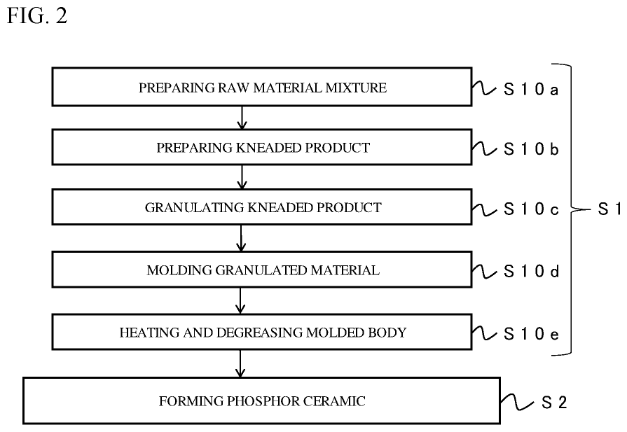

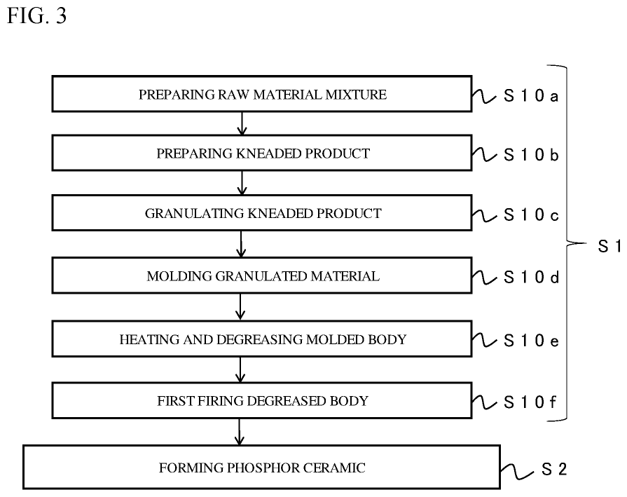

A method for manufacturing the precursor is described. The precursor is either a molded body containing aluminum nitride or a sintered body containing aluminum nitride. FIG. 2 is a flowchart illustrating an example of a method for manufacturing a phosphor ceramic, the method including a method for manufacturing a precursor in a case in which the precursor is a molded body containing aluminum nitride. FIG. 3 is a flowchart illustrating an example of a method for manufacturing a phosphor ceramic, the method including a method for manufacturing a precursor in a case in which the precursor is a sintered body containing aluminum nitride. Hereinafter, the molded body containing aluminum nitride is referred to simply as a molded body, and the sintered body containing aluminum nitride is referred to simply as a sintered body.

An example of a method for manufacturing a precursor for a case in which the precursor is a molded body or a case in which the precursor is a sintered body is described with reference to FIG. 2 and FIG. 3. When the precursor is a molded body, the method for manufacturing the molded body includes a step S10a of preparing a raw material mixture and a step S10d of molding a granulated material. If necessary, the manufacturing method may include any or all of a step S10b of preparing a kneaded product, a step S10c of granulating the kneaded product, and a step S10e of heating and degreasing the molded body. When the precursor is a sintered body, the method further includes a step S10f of a first firing of a degreased body.

Step S10a of Preparing Raw Material Mixture In the step of preparing the precursor, a powder of aluminum nitride and, if necessary, a sintering aid containing a rare earth element are prepared. Hereinafter, the aluminum nitride powder is also referred to simply as AlN powder.

Aluminum Nitride Powder

The proportion of the AlN powder in the raw material mixture is in a range from 90 mass % to 99.9 mass % relative to 100 mass % of the raw material mixture. Therefore, the base material of the precursor to be manufactured is aluminum nitride. Moreover, in relation to 100 mass % of the raw material mixture, the proportion of the AlN powder in the raw material mixture may be in a range from 93 mass % to 99.7 mass %, a range from 95 mass % to 99.6 mass %, or in a range from 95 mass % to 99.5 mass %.

A median particle diameter Da of the AlN powder may be in a range from 0.1 μm to 5 μm, from 0.3 μm to 3 μm, or from 0.5 μm to 1.5 μm. Thereby, a dense sintered body can be formed, and a phosphor ceramic having high thermal conductivity can be formed. The median particle diameter Da of the AlN powder refers to the particle diameter corresponding to 50% in a volume-based cumulative particle size distribution measured by the Coulter counter method. The particle size distribution can be measured using a particle size distribution measuring device (for example, the CMS available from Beckman Coulter Inc.).

The AlN powder may contain oxygen. In relation to the total amount of the AlN powder, the content of oxygen in the AlN powder is preferably 2 mass % or less, and more preferably 1.5 mass % or less. By setting the oxygen content to such an amount, point defects of Al in the lattice of the aluminum nitride crystal phase constituting the base material of the phosphor ceramic can be decreased, the amount of the grain boundary phase composed of an oxide can be reduced, and a phosphor ceramic having high thermal conductivity can be manufactured.

The AlN powder preferably does not include any metal elements except aluminum. The content of the metal element other than aluminum in relation to the total amount of the AlN powder may be, for example, 1 mass % or less, 0.5 mass % or less, mass % or less, or 0.01 mass % or less. Through this, coloration of the formed phosphor ceramic can be reduced. In addition, a decrease in thermal conductivity can also be reduced. In particular, the content of metal elements other than aluminum in relation to the total amount of the AlN powder is preferably 100 ppm or less, and the content of iron is particularly preferably 20 ppm or less. In this way, block coloration of the phosphor ceramic can be reduced. The content of the metal elements excluding aluminum in the AlN powder can be measured by a high-frequency inductively coupled plasma atomic emission spectrometer (ICP-AES).

The reflectivity of the AlN powder in a wavelength range from 400 nm to 700 nm is 50% or greater, or 70% or greater. As a result, the reflectance of the formed phosphor ceramic is increased, and the emission intensity when the phosphor ceramic is excited by the excitation light source can be increased.

Sintering Aid

The raw material mixture may contain a sintering aid. When the raw material mixture contains a sintering aid, aluminum nitride crystals are densely bonded to each other, and a precursor having high thermal conductivity can be formed. Examples of the sintering aid include compounds such as oxides and fluorides containing a rare earth element. Examples of the oxide containing a rare earth element include yttrium oxide, europium oxide, lanthanum oxide, cerium oxide, ytterbium oxide, praseodymium oxide, neodymium oxide, samarium oxide, gadolinium oxide, dysprosium oxide, and erbium oxide. The most preferred sintering aid is yttrium oxide. Yttrium oxide easily forms a liquid phase with oxygen contained in the AlN powder, and facilitates a dense sintered body.

The content of the sintering aid in the raw material mixture may be, in relation to 100 mass % of the raw material mixture, in a range from 0.05 mass % to 10 mass %, a range from 0.1 mass % to 7 mass %, or a range from 0.1 mass % to 5 mass %. The sintering aid need not be contained in the raw material mixture.

The sintering aid is preferably a powder. A median particle diameter De of the sintering aid may be in a range from 0.1 μm to 5 μm, a range from 0.2 μm to 4 μm, or a range from 0.3 μm to 3 μm. The median particle diameter De of the sintering aid refers to the particle diameter corresponding to 50% in a volume-based cumulative particle size distribution measured by the Coulter counter method. A particle diameter ratio De/Da of the median particle diameter De of the sintering aid to the median particle diameter Da of the AlN powder is preferably in a range from 0.1 to 20. Through this, particles constituting the raw material mixture are easily dispersed, and a sintered body having a high density is easily formed. The particle diameter ratio De/Da of the median particle diameter De of the sintering aid to the median particle diameter Da of the AlN powder is more preferably in a range from 0.2 to 18, in a range from 0.3 to 15, or in a range from 0.5 to 10. By adopting such a particle diameter ratio, deviation in the state after mixing with the AlN powder is less likely to occur.

The raw material mixture containing aluminum nitride and the sintering aid can be formed by dry mixing or wet mixing. Dry mixing refers to mixing the aluminum nitride and each compound in the absence of a liquid. Wet mixing refers to mixing of raw materials in a state of containing an organic solvent or water. The preferred mixing method is dry mixing. In the case of dry mixing, the raw material mixture may include both large and small particles of the sintering aid. Relatively large sintering aid particles are considered likely to produce a localized liquid phase. Conceivably, the localized liquid phase facilitates rearrangement of the aluminum nitride particles, facilitating formation of a dense sintered body. Further, aluminum nitride is sensitive to moisture, and thus dry mixing without the use of moisture is preferred. Further, dry mixing can simplify the manufacturing process compared to wet mixing. For dry mixing, a device such as a super mixer, an axial mixer, a Henschel mixer, a ribbon mixer, or a locking mixer can be used. For wet mixing, a device such as a ball mill or media agitation mill can be used.

Step S10b of Preparing Kneaded Product

The step of preparing the precursor may include a step of preparing a kneaded product by kneading the raw material mixture and an organic substance. Examples of the organic substance include those used as binders, lubricants, and plasticizers. The organic substance included in the kneaded product may be in an amount that can sufficiently mix the raw material mixture and the organic substance without affecting the properties of the sintered body to be formed. The content of the organic substance included in the kneaded product is preferably in a range from 10 parts by mass to 25 parts by mass per 100 parts by mass of the raw material mixture. The kneaded product may further contain a coupling agent. The coupling agent is used to enhance the dispersibility between the raw material mixture and the organic substance. An auxiliary agent such as the coupling agent may be added to the kneaded product in a range that does not affect the properties of the sintered body to be formed.

Examples of the organic substance as a binder include at least one thermoplastic resin selected from the group consisting of low-density polyethylene, medium-density polyethylene, high-density polyethylene, low molecular weight polyethylene, ethylene-vinyl acetate copolymer, ethylene acrylate copolymer, polypropylene, atactic polypropylene, polystyrene, polyacetal, polyamide, and methacrylic resin. In addition to these thermoplastic resins, examples of binders include waxes such as paraffin wax and microcrystalline wax. These binders may be used alone or in combination of two or more.

Examples of the organic substance as a lubricant include hydrocarbon-based lubricants such as liquid paraffin and paraffin wax, and fatty acid-based lubricants such as stearic acid and lauryl acid. These lubricants may be used alone or in combination of two or more.

Examples of the organic substance as a plasticizer include phthalates, adipates, and trimellitates. These plasticizers may be used alone or in combination of two or more.

Step S10c of Granulating Kneaded Product

The step of preparing the precursor may include a granulation step of granulating the kneaded product. The kneaded product may be granulated into a granular form or a pellet form prior to molding the molded body. The kneaded product having a granular form or a pellet form can be formed by using a known device such as a pulverizer, an extruder, or a pelletizer.

Step S10d of Molding Granulated Material

The step of preparing the precursor may include a step of molding the raw material mixture, a kneaded product of the raw material mixture and an organic substance, or a granulated material formed by granulating the kneaded product. A molded body is formed in this manner. Examples of the method for forming the molded body include an injection molding method, a press molding method using a mold, a cold isostatic pressing method, an extrusion molding method, a doctor blade method, and a casting method. The method for forming a molded body is preferably an injection molding method. A molded body having a desired shape can be formed. The shape of the molded body in a plan view may be, for example, a circle, an ellipse, a rectangle, a square, or another polygon, or may be a composite shape formed by combining a plurality of shapes. The molded body may also have a recessed portion and a convex portion.

Step S10e of Heating and Degreasing Molded Body

The step of preparing the precursor may include a step of heating and degreasing the molded body. By degreasing the molded body, cracking of the sintered body due to carbon remaining in the kneaded product can be reduced, and the yield can be increased. Oxidation of the sintered body can also be suppressed. Further, depending on the type of organic substance, heat may be rapidly generated in the temperature range described above, but such a rapid increase in temperature can be suppressed by heating in a nitrogen atmosphere. As a result, deterioration of the furnace can be suppressed. In a case in which the molded body is heated and degreased, the method preferably includes heating in a range from 400° C. to 700° C. in a nitrogen atmosphere. In the present specification, a nitrogen atmosphere refers to a case in which the amount of nitrogen is at least the volume percentage of nitrogen contained in the atmosphere. The nitrogen in the nitrogen atmosphere need only be 80 vol % or greater, and is preferably 90 vol % or greater, more preferably 99 vol % or greater, and even more preferably 99.9 vol % or greater. The content of oxygen in the nitrogen atmosphere may be in a range from 0.01 vol % to 20 vol %, or may be in a range from 0.1 vol % to 10 vol %. The atmospheric pressure at which the heating is performed is, for example, ambient pressure. Furthermore, the heating may be performed under a pressurized environment or a depressurized environment. Further, degreasing can be performed by using a known method. The carbon amount in the molded body formed by degreasing the molded kneaded product is, for example, preferably 1000 ppm or less, and more preferably 500 ppm or less. The carbon amount in the molded body after degreasing can be measured, for example, by a non-dispersive infrared absorption method. The degreasing time during which heating is implemented need only be an amount of time during which the organic substance in the molded body can be degreased such that the carbon amount in the molded body becomes 1000 ppm or less. Specifically, the time during which heating is implemented for degreasing (holding time of maximum temperature) is preferably in a range from 0.1 hours to 50 hours, and is changed, as appropriate, according to the shape of the molded body to be degreased.

Step S10f of First Firing of Degreased Body

The precursor is preferably a sintered body containing aluminum nitride as the base material. This is because the thermal conductivity of such a sintered body is higher than that of the molded body. When the precursor is a sintered body, a step of firing the degreased body to form a sintered body may be included as described in FIG. 3. Alternatively, the method may include a step of firing the molded body to form a sintered body. Firing the molded body or the degreased body to form a sintered body as described above is also referred to as a first firing in the present specification. The temperature in the first firing is also referred to as a first firing temperature. The atmosphere during the first firing is also referred to as a first firing atmosphere.

The first firing temperature is preferably in a range from 1700° C. to 2050° C. By firing at such a temperature, the aluminum nitride particles are densely bonded to each other by the liquid phase formed between the aluminum nitride particles, a crystal phase is formed, and a sintered body having high thermal conductivity can be formed. Further, the first firing temperature is preferably in a range from 1750° C. to 2050° C., more preferably in a range from 1800° C. to 2050° C., and even more preferably in a range from 1850° C. to 2050° C. Setting the first firing temperature to such a range can further improve the thermal conductivity of the precursor.

The first firing atmosphere is preferably the above-described nitrogen atmosphere. By carrying out the first firing in a nitrogen atmosphere, the aluminum nitride is less likely to decompose, and a sintered body having high thermal conductivity can be formed. Further, for the first firing atmosphere, a gas containing nitrogen can be continuously or intermittently supplied to stably maintain the nitrogen atmosphere.

The pressure in the first firing atmosphere is, for example, near atmospheric pressure (101.32 kPa), and is preferably 50 kPa or less by gauge pressure. An environment in a range from 0 kPa to 50 kPa by gauge pressure can be relatively easily reached, and thus productivity is improved.

The first firing time need only be an amount of time in which a dense sintered body can be formed. Specifically, the first firing time may be preferably in a range from 0.5 hours to 100 hours. The first firing time is more preferably in a range from 10 hours to 70 hours, and even more preferably in a range from 20 hours to 45 hours. Through this, unnecessary oxygen in the molded body or the degreased body is discharged, and a denser sintered body can be formed.

To reduce the oxygen amount in the sintered body, the first firing is preferably implemented using a carbon furnace that uses carbon in an internal furnace member such as a heating element or a heat insulating material. A furnace other than a carbon furnace may be used as long as the first firing temperature can be maintained.

A setter and crucible on which the molded body or degreased body is placed are preferably ones that are not deformed or degraded at the first firing temperature. The material of the setter or the crucible is preferably a nitride such as boron nitride or aluminum nitride. A setter or crucible made of a material containing a nitride with a purity of 95 mass % or higher is preferably used.

The method for manufacturing the sintered body may further include a step of dividing into individual pieces. The shape of the sintered body in a plan view after dividing into individual pieces may be, for example, a circle, an ellipse, a rectangle, a square, or another polygon, and may include a recessed portion, a convex portion, or the like.

In addition to the method described above, the first firing step may be executed by, for example, a hot isostatic pressing method or a spark plasma sintering method. Note that the spark plasma sintering method is also referred to as a pulsed electric current sintering method. A dense precursor can be formed with these methods as well.

The sintered body containing aluminum nitride preferably contains oxygen, and the oxygen content is preferably 0.3 mass % or less. When the sintered body contains oxygen at such an amount, the grain boundary phase generated between aluminum nitride particles in the sintered body can be reduced, and therefore the thermal conductivity can be further improved. The thermal conductivity of the grain boundary phase is lower than that of the aluminum nitride, and therefore the thermal conductivity of the sintered body containing aluminum nitride can be improved by reducing this grain boundary phase. In addition, even when the precursor is doped with an element serving as a light emission center in the step of forming the phosphor ceramic described below, the phosphor ceramic can have relatively high thermal conductivity. Moreover, the oxygen content of the sintered body containing aluminum nitride is in a range from greater than 0 mass % to 0.1 mass %, and more preferably in a range from greater than 0 mass % to 0.01 mass %. As a result, the thermal conductivity of the formed sintered body is further improved, and the sintered body can have translucency. For example, when one surface of a sintered body having a thickness of 2 mm is irradiated with excitation light having a peak wavelength of 380 nm, excitation light having a peak wavelength of 380 nm is extracted from the surface of the side opposite the surface irradiated with the excitation light. Similarly, light emitted from the phosphor ceramic can also be extracted from the surface opposite of the side opposite the surface irradiated with the excitation light. This is because the grain boundary phase is reduced, and the absorption of light by the grain boundary phase is suppressed. The energy gap of aluminum nitride is approximately 6.2 eV, and therefore a sintered body containing aluminum nitride is translucent to light having a peak wavelength of around 200 nm or higher.

The content of oxygen contained in the precursor can be measured using an oxygen/nitrogen analyzer after acidolysis of the sintered body. Note that the oxygen content of the sintered body may be equal to or less than the detection limit value of the oxygen/nitrogen analyzer.

The thermal conductivity of the sintered body can be set to, for example, a range from 150 W/(m·K) to 270 W/(m·K), preferably a range from 200 W/(m·K) to 270 W/(m·K), and more preferably a range from 220 W/(m·K) to 270 W/(m·K).

Step S2 of Forming Phosphor Ceramic

The precursor can be contacted with a gas containing manganese to form a phosphor ceramic. The step of forming the phosphor ceramic preferably includes firing the precursor in an atmosphere containing manganese at a temperature in a range from 1600° C. to 2000° C. The aluminum nitride crystal phase in the sintered body containing aluminum nitride is more easily doped with manganese, and a phosphor ceramic can be formed. In the present specification, firing in the step of forming the phosphor ceramic is also referred to as a second firing. The firing temperature in the step of forming the phosphor ceramic is also referred to as a second firing temperature. The firing atmosphere in the step of forming the phosphor ceramic is also referred to as a second firing atmosphere.

The step of forming the phosphor ceramic preferably includes subjecting the precursor and a manganese-containing compound disposed so as not to be in direct contact with the precursor to a second firing at a temperature in a range from 1600° C. to 2000° C. A gas containing manganese is formed from the manganese-containing compound, and the gas is brought into contact with the precursor to dope the precursor with manganese. Thereby, a phosphor ceramic that emits light upon receiving excitation light can be formed. In the process of the second firing, the precursor generates a liquid phase to form a dense sintered body. This enables forming of a phosphor ceramic having high thermal conductivity.

The second firing temperature may be in a range from 1600° C. to 2000° C. The second firing temperature is preferably in a range from 1700° C. to 2000° C., a range from 1750° C. to 1950° C., or a range from 1750° C. to 1900° C. Through this, the luminous intensity can be increased while thermal conductivity is maintained.

The second firing atmosphere is preferably a nitrogen atmosphere. The content of oxygen in the nitrogen atmosphere may be in a range from 0.01 vol % to 20 vol %, or may be in a range from 0.1 vol % to 10 vol %. In addition, the atmosphere during the second firing may be an argon (Ar) atmosphere.

The second firing may be carried out, for example, at normal pressure or may be carried out in a pressurized environment. When the second firing is carried out in a pressurized environment, the atmospheric pressure under which the second firing is implemented is preferably in a range from 0.01 MPa to 0.5 MPa in terms of gauge pressure, may be in a range from 0.01 MPa to 0.1 MPa in terms of gauge pressure, or may be in a range from 0.01 MPa to 0.08 MPa in terms of gauge pressure.

The time for carrying out the second firing may be any time as long as the manganese is doped into the phosphor ceramic, and the time thereof may be set, as appropriate. For example, the time may be set in a range from 0.1 hours to 20 hours, and may be set in a range from 0.5 hours to 10 hours.

As the compound containing manganese, for example, one or more selected from the group consisting of oxides, nitrides, hydroxides, halides, and carbonates may be used. Examples of the compound containing manganese include manganese oxides (MnO, MnO₂, or Mn₂O₃), manganese(II) fluoride (MnF₂), and manganese carbonate (MnCO₃). Manganese oxides are stable at ordinary temperature or in the atmosphere, and therefore are preferably used as the compound containing manganese.

In the step of forming the phosphor ceramic, the gas containing manganese is preferably a manganese-containing gas formed by reducing manganese oxide. An example of a method for reducing manganese oxide includes a method in which a precursor and manganese oxide are placed in a carbon furnace and fired at a temperature in a range from 1600° C. to 2000° C., and thereby the manganese oxide is reduced, and a gas containing manganese is formed. Another example is a method in which a precursor and manganese oxide are placed in a furnace, a reducing agent such as carbon is then inserted into the furnace, and the materials are fired at a temperature in a range from 1600° C. to 2000° C., and thereby the manganese oxide is reduced, and a gas containing manganese is formed.

The charging amount of the manganese compound per 1 g of the precursor may be, for example, in a range from 0.15 g to 3.0 g, or in a range from 0.2 g to 2.5 g.

According to one example of the manufacturing method described above, a phosphor ceramic having high thermal conductivity is formed. The phosphor ceramic contains aluminum nitride and manganese.

A method for manufacturing the phosphor ceramic was described above, but, for example, the phosphor ceramic may be formed by steps like those described below. Descriptions of overlapping details are omitted.

### First Modified Example

In the step of forming the phosphor ceramic, instead of disposing the manganese compound so as not to be in direct contact with the precursor, a manganese-containing compound may be brought into contact with the surface of the precursor and fired at a temperature in a range from 1600° C. to 2000° C. This enables forming of a phosphor ceramic having high thermal conductivity.

### Second Modified Example

In the step of forming the phosphor ceramic, instead of disposing the manganese compound so as not to be in direct contact with the precursor, the gas containing manganese may be introduced into the atmosphere, and the precursor may be fired at a temperature in a range from 1600° C. to 2000° C. This enables forming of a phosphor ceramic having high thermal conductivity. For example, the gas containing manganese may be formed by firing the compound containing manganese at a temperature in a range from 1600° C. to 2000° C. in a furnace different from the furnace containing the precursor. The formed gas may be introduced into the furnace containing the precursor, and the precursor may be fired at a temperature in a range from 1600° C. to 2000° C.

### Third Modified Example

In the step of forming the phosphor ceramic, the gas containing manganese may be formed by using manganese metal instead of forming the gas containing manganese from the compound containing manganese. The formed gas may be brought into contact with the precursor, and the precursor may be fired at a temperature in a range from 1600° C. to 2000° C. This enables forming of a phosphor ceramic having high thermal conductivity.

### Application Example

Light-emitting Device

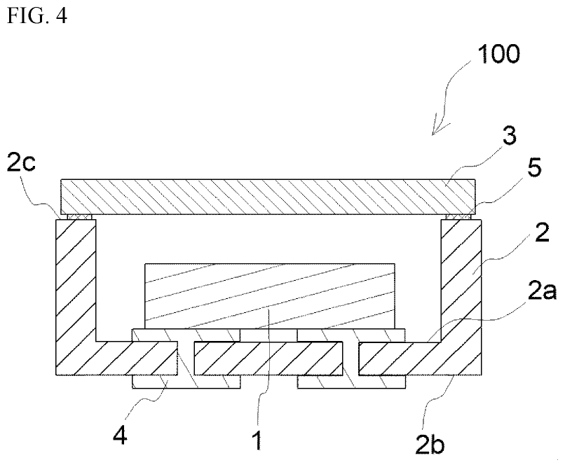

FIG. 4 is a cross-sectional view illustrating an example of a light-emitting device containing a phosphor ceramic. The light-emitting element 1 is disposed on a recess bottom surface 2a of a ceramic substrate 2 having a recessed portion. The ceramic substrate 2 has the recess bottom surface 2a and a lower surface 2b located at a side opposite the recess bottom surface 2a. The light-emitting element 1 is electrically connected to a wiring 4. The wiring 4 includes an anode and a cathode. The wiring 4 is wired from the recess bottom surface 2a to the lower surface 2b via a through hole penetrating the ceramic substrate 2. In addition, a light-transmissive member 3 is disposed on an upper surface 2c of the same side as the recess bottom surface 2c of the ceramic substrate 2. The light-transmissive member 3 is adhered by an adhesive 5 disposed on the upper surface 2c of the ceramic substrate 2.

The light-emitting element 1 is a semiconductor light-emitting element having a peak wavelength in a range from 230 nm to 330 nm. The light-emitting element 1 is, for example, In_{X}Al_{Y}Ga_{1-X-Y}N (provided that, 0≤X, 0≤Y, and X+Y≤1). An example of the light-emitting element 1 that can be used includes an element having a pair of positive and negative electrodes on the same surface side. The light-emitting element 1 may be, for example, flip-chip mounted onto the wiring 4. In a case in which the light-emitting element 1 is flip-chip mounted on the wiring 4, the surface of the side opposite the surface on which the pair of electrodes is formed is a light extraction surface. The number of light-emitting elements 1 arranged in one light-emitting device is required to be one or more.

The phosphor ceramic of the present embodiment can also be used as the ceramic substrate 2. The ceramic substrate 2 containing the phosphor ceramic has high thermal conductivity and can efficiently dissipate heat generated by the light-emitting element and heat generated by the light-transmissive member 3. The ceramic substrate 2 can also emit light upon receiving light from the light-emitting element. This feature may be utilized, for example, to cause the ceramic substrate 2 to function as a marker for notifying the surroundings of the generation of ultraviolet light. In addition, the ceramic substrate 2 may also have a reflective film formed on the side surfaces in the recessed portion. Through this, the light emitted from the light-emitting element 1 is reflected, and the luminance of the light-emitting device can be increased. The ceramic substrate 2 can be formed, for example, by second firing a precursor including the recessed portion, the precursor being molded by an injection molding method.

A phosphor ceramic of the present embodiment can be used as the light-transmissive member 3. The phosphor ceramic contains aluminum nitride as a base material and manganese. The light-transmissive member 3 can emit light when excited by light emitted from the light-emitting element 1. The light-transmissive member 3 emits light having a peak in a wavelength range from 590 nm to 620 nm. In addition, the thermal conductivity can be improved and the heat dissipation property can be enhanced by configuring the light-transmissive member 3 to include the phosphor ceramic of the present embodiment. The thickness of the light-transmissive member 3 is, for example, in a range from 50 μm to 1000 μm, in a range from 50 μm to 500 μm, in a range from 60 μm to 450 μm, or in a range from 70 μm to 400 μm. The light-transmissive member 3 can be formed by, for example, molding through injection molding and subjecting the precursor to the second firing.

The phosphor ceramic may be contained in only one of either the light-transmissive member 3 or the ceramic substrate 2, or may be contained in both. If the phosphor ceramic is contained in both the light-transmissive member 3 and the ceramic substrate 2, heat generated by the light-transmissive member 3 can be efficiently dissipated through the ceramic substrate 2.

### EXAMPLES

The present disclosure will be described in detail below by using examples, but the present disclosure is not limited to these examples.

### Example 1

Step of Preparing a Precursor

A raw material mixture was formed by dry mixing 95 mass % of AlN powder and 5 mass % of yttrium oxide powder. The median particle diameter Da of the AlN powder was 1.1 μm, and the median particle diameter De of the yttrium oxide powder was 0.7 μm. The ratio of De to Da (De/Da) was 0.64. 15 parts by mass of paraffin wax was added as a binder per 100 parts by mass of the raw material mixture, the mixture was kneaded using a kneader, and a kneaded product was formed. The kneaded product was fed into an injection molding machine and molded into a shape having a size of 13 mm (length)×13 mm (width)×3 mm (thickness), and a molded body was formed. The molded body was degreased for three hours in a nitrogen atmosphere at a temperature of 500° C. and under atmospheric pressure (101.32 kPa), and a degreased body was formed. The carbon amount in the degreased body was 500 ppm or less. In Example 1, the formed degreased body was used as a precursor.

Step of Forming Phosphor Ceramic

1.6 g of the precursor was placed on a boron nitride setter placed in a crucible made of boron nitride. Further, 1.0 g of manganese dioxide powder was placed in the crucible. The crucible was introduced into a carbon furnace, and the precursor was second fired. The second firing was carried out in a nitrogen atmosphere for 1 hour at a gauge pressure of 30 kPa. The second firing temperature was 1800° C. A phosphor ceramic was formed by the second firing.

### Example 2

Step of Preparing a Precursor

A degreased body formed under the same conditions as in Example 1 was subjected to the first firing, and a sintered body was formed. The first firing was carried out for 35 hours in a nitrogen atmosphere at a temperature of 1950° C. and a gauge pressure of 0.03 MPa. The oxygen content in the sintered body measured using an oxygen/nitrogen analyzer (EMGA-820, available from Horiba, Ltd.) was equal to or less than the detection limit value, and was at least less than 0.1 mass %.

Step of Forming Phosphor Ceramic

A phosphor ceramic was formed by implementing the step of forming a phosphor ceramic under the same conditions as in Example 1 with the exception that 0.25 g of manganese dioxide was used, and the second firing was carried out at 1700° C. for 2 hours.

### Example 3

A phosphor ceramic was formed under the same conditions as in Example 2 with the exception that the second firing was carried out at 1800° C.

### Example 4

A phosphor ceramic was formed under the same conditions as in Example 2 with the exception that the second firing was carried out at 1900° C.

### Example 5

A phosphor ceramic was formed under the same conditions as in Example 2 with the exception that the second firing was carried out at 2000° C.

### Example 6

A phosphor ceramic was formed under the same conditions as in Example 2 with the exception that 0.5 g of manganese dioxide was used, and the second firing was carried out at 1600° C.

### Example 7

A phosphor ceramic was formed under the same conditions as in Example 6 with the exception that the second firing was carried out at 1700° C.

### Example 8

A phosphor ceramic was formed under the same conditions as in Example 6 with the exception that the second firing was carried out at 1800° C.

### Example 9

A phosphor ceramic was formed under the same conditions as in Example 6 with the exception that the second firing was carried out at 1900° C.

### Example 10

A phosphor ceramic was formed under the same conditions as in Example 6 with the exception that the second firing was carried out at 2000° C.

### Example 11

A phosphor ceramic was formed under the same conditions as in Example 2 with the exception that 1.2 g of manganese dioxide was used, and the second firing was carried out at 1800° C.

### Example 12

A phosphor ceramic was formed under the same conditions as in Example 11 with the exception that the second firing was carried out at 1900° C.

### Example 13

A phosphor ceramic was formed under the same conditions as in Example 2 with the exception that 2.4 g of manganese dioxide was used, and the second firing was carried out at 1900° C.

### Reference Example 1

An aluminum nitride ceramic according to Reference Example 1 was formed under the same conditions as in Example 2 with the exception that 0.15 g of manganese dioxide was used, and the second firing was carried out at 1900° C.

### Comparative Example 1

A raw material mixture was formed by dry mixing 95 mass % of AlN powder, 4 mass % of yttrium oxide powder, and 1 mass % of manganese dioxide powder. 15 parts by mass of paraffin wax were added as a binder per 100 parts by mass of the raw material mixture, and the mixture was kneaded using a kneader to form a kneaded product. The kneaded product was fed into an injection molding machine, and the kneaded product was molded into a shape having a size of 13 mm (length)×13 mm (width)×3 mm (thickness). The molded kneaded product was heated and degreased in a nitrogen flowing atmosphere (nitrogen gas 99 vol %) at 500° C. under atmospheric pressure (101.32 kPa) for 3 hours to form a molded body. The formed molded body was placed on a setter made of boron nitride with the setter being placed in a crucible made of boron nitride, the molded body on the setter was then inserted into a carbon furnace that used carbon as an inner furnace material of the heating element or insulating material, and fired in a nitrogen atmosphere (nitrogen gas 100 vol %) at 1900° C. at gauge pressure (0.03 MPa) for 1 hour to form a phosphor ceramic.

Evaluation

XRD

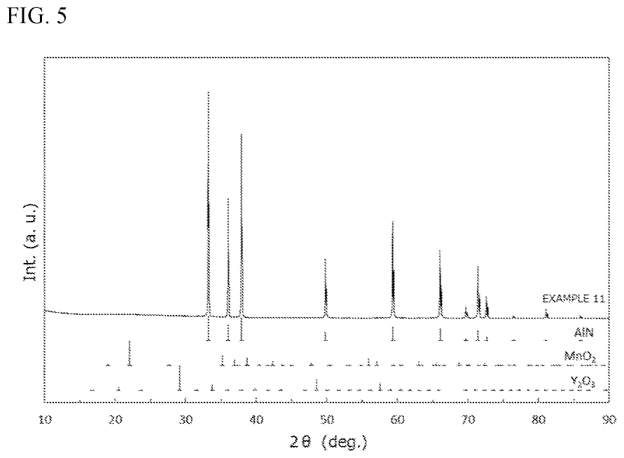

An X-ray diffraction (XRD) pattern of the phosphor ceramic according to Example 11 was measured using an X-ray diffractometer (SmartLab, available from Rigaku Corporation). The X-ray source was CuKα1 rays (λ=0.154059 nm), and the XRD pattern was measured under conditions including a tube voltage of 45 kV and a tube current of 200 mA. The formed XRD patterns indicating the diffraction intensity with respect to the diffraction angle (2θ) are shown in FIG. 5. FIG. 5 is a graph illustrating, in order from the top, the XRD pattern of the phosphor ceramic according to Example 11 and X-ray diffraction patterns registered as references in the Inorganic Crystal Structure Database (ICSD). The reference XRD patterns are, in order from the top, the X-ray diffraction patterns of AlN, MnO₂, and Y₂O₃.

As illustrated in FIG. 5, the phosphor ceramic according to Example 11 has peaks at substantially the same positions as those of the diffraction angles 2θ of the XRD pattern of AlN, confirming that the phosphor ceramic of Example 11 has substantially the same structure as that of AlN.

Excitation Spectrum

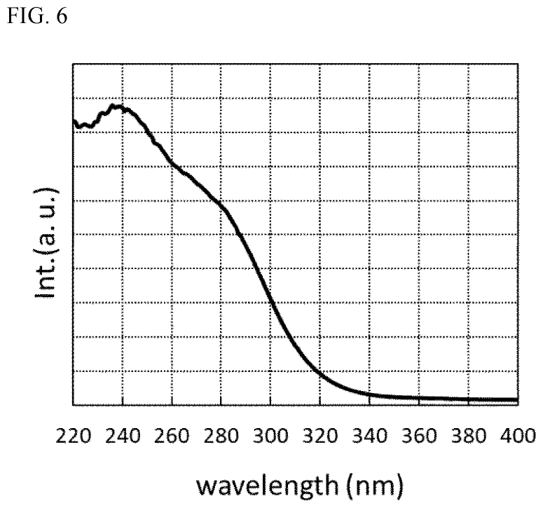

The excitation spectrum of the phosphor ceramic according to Example 11 was measured using a spectrophotometer (F-4500, available from Hitachi High-Tech Science Corporation). FIG. 6 illustrates an excitation spectrum in which the horizontal axis represents the wavelength and the vertical axis represents the intensity. As illustrated in FIG. 6, the excitation spectrum of the phosphor ceramic according to Example 11 was confirmed to have a peak in a range from 230 nm to 250 nm. In addition, the excitation spectrum of the phosphor ceramic according to Example 11 was also confirmed to have a shoulder structure in a range from 260 nm to 300 nm. The resulting excitation spectrum has a shape and peak position similar to those of the excitation spectrum disclosed in Non-Patent Document 1. Therefore, it is presumed from the excitation spectrum that the phosphor ceramic is an aluminum nitride phosphor ceramic in which manganese is activated by the aluminum nitride.

Emission Spectrum

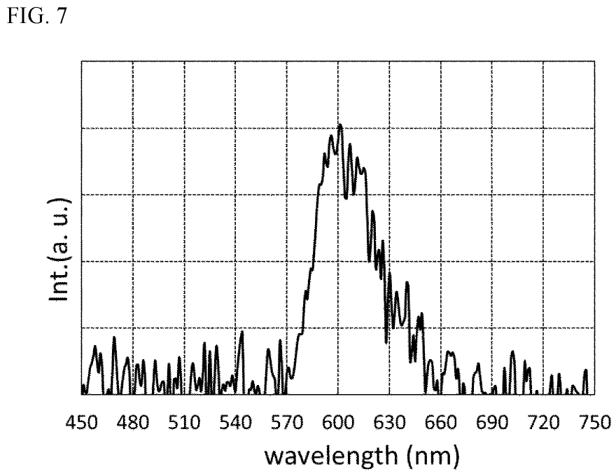

The phosphor ceramic according to Example 11 was irradiated with excitation light having an emission peak wavelength of 254 nm as the excitation light source, and the emission spectrum was measured at room temperature (25° C.±5° C.). FIG. 7 illustrates an emission spectrum in which the horizontal axis represents the wavelength and the vertical axis represents the intensity. As illustrated in FIG. 7, the phosphor ceramic was confirmed to have an emission peak wavelength in a range of 590 nm to 620 nm. In addition, the phosphor ceramic was confirmed to have a peak at a position of approximately 600 nm. Note that when the emission spectra of the phosphor ceramics according to Example 1 and Example 8 were measured in the same manner, in each case, the emission peak wavelength did not change for the most part. The resulting emission spectrum has a shape and a peak position similar to those of the emission spectrum disclosed in Non-Patent Document 1. Therefore, it is presumed from the emission spectrum that the phosphor ceramic is an aluminum nitride phosphor ceramic in which manganese is activated by the aluminum nitride.

The phosphor ceramics according to Examples 1 to 13 and Comparative Example 1 were irradiated with light having a wavelength of 254 nm. In each case, the luminescence of the phosphor ceramic could be visually confirmed. Afterglow was observed for about one minute after stopping irradiation with the light having a wavelength of 254 nm. In addition, when the phosphor ceramics were irradiated with light having a wavelength of 254 nm for 30 seconds, a phenomenon was visually confirmed in which light emission became stronger than that immediately after the startup of irradiation with light. Note that when the phosphor ceramic of Reference Example 1 was irradiated with the light having a wavelength of 254 nm, light emission could not be visually confirmed.

Thermal Conductivity

The thermal conductivity λ values of the samples of the phosphor ceramics according to Examples 1 to 13, the phosphor ceramic according to Comparative Example 1, and the aluminum nitride ceramic according to Reference Example 1 were determined on the basis of the specific heat capacity Cp and the measured apparent density and thermal diffusivity a. The specific heat capacity Cp was determined using 0.72 KJ/(kg·K), which is the specific heat capacity of aluminum nitride. The results are shown in Tables 1 and 2.

Element Analysis

Each sample of Examples 1 to 13, Comparative Example 1, and Reference Example 1 was subjected to an element analysis to measure the contents of aluminum, yttrium, oxygen, and manganese. The contents of aluminum, yttrium, and manganese were determined using an ICP emission spectrometer. The content of oxygen was determined using an oxygen/nitrogen analyzer. Example 13, Comparative Example 1, and Reference Example 1 were subjected to a trace analysis of manganese. The results of Examples 1 to 13 and Reference Example 1 are shown in Table 1. The results of Comparative Example 1 are shown in Table 2.

TABLE 1

| | Production Conditions | | | Evaluation Results | | | | | |
|---|---|---|---|---|---|---|---|---|---|
| | | | Second firing | Thermal | Thermal | Apparent | | | |
| | | MnO₂ | temperature | conductivity | diffusivity | density | Y | Mn | O |
| | Precursor | (g) | (° C.) | (W/(m · K)) | (mm²/s) | (g/cm³) | (Mass %) | (ppm) | (Mass %) |
| Example 1 | Degreased | 1.0 | 1800 | 162 | 68.6 | 3.28 | 3.9 | <50 | 2.2 |
| | body | | | | | | | | |
| Example 2 | Sintered | 0.25 | 1700 | 246 | 104.5 | 3.27 | <0.1 | <10 | <0.1 |
| | body | | | | | | | | |
| Example 3 | Sintered | 0.25 | 1800 | 234 | 99.2 | 3.27 | <0.1 | <10 | <0.1 |
| | body | | | | | | | | |
| Example 4 | Sintered | 0.25 | 1900 | 225 | 95.6 | 3.27 | <0.1 | <10 | <0.1 |
| | body | | | | | | | | |
| Example 5 | Sintered | 0.25 | 2000 | 224 | 95.0 | 3.27 | <0.1 | <10 | <0.1 |
| | body | | | | | | | | |
| Example 6 | Sintered | 0.5 | 1600 | 236 | 100.3 | 3.27 | <0.1 | <10 | <0.1 |
| | body | | | | | | | | |
| Example 7 | Sintered | 0.5 | 1700 | 245 | 104.0 | 3.27 | <0.1 | <10 | <0.1 |
| | body | | | | | | | | |
| Example 8 | Sintered | 0.5 | 1800 | 235 | 99.9 | 3.27 | <0.1 | <10 | <0.1 |
| | body | | | | | | | | |
| Example 9 | Sintered | 0.5 | 1900 | 220 | 93.4 | 3.27 | <0.1 | <10 | <0.1 |
| | body | | | | | | | | |
| Example 10 | Sintered | 0.5 | 2000 | 246 | 104.4 | 3.27 | <0.1 | <10 | <0.1 |
| | body | | | | | | | | |
| Example 11 | Sintered | 1.2 | 1800 | 246 | 104.6 | 3.27 | <0.1 | <10 | <0.1 |
| | body | | | | | | | | |
| Example 12 | Sintered | 1.2 | 1900 | 230 | 98.0 | 3.26 | <0.1 | <10 | <0.1 |
| | body | | | | | | | | |
| Example 13 | Sintered | 2.4 | 1900 | 232 | 98.8 | 3.26 | <0.1 | 50 | <0.1 |
| | body | | | | | | | | |
| Reference | Sintered | 0.15 | 1900 | 220 | 93.4 | 3.27 | <0.1 | <1 | <0.1 |
| Example 1 | body | | | | | | | | |

TABLE 2

| | Production Conditions | | | | Evaluation Results | | | | | |
|---|---|---|---|---|---|---|---|---|---|---|
| | AlN | | | Firing | Thermal | Thermal | Apparent | | | |
| | powder | Y₂O₃ | MnO₂ | temperature | conductivity | diffusivity | density | Y | Mn | O |
| | (Mass %) | (Mass %) | (Mass %) | (° C.) | (W/(m · K)) | (mm²/s) | (g/cm³) | (Mass %) | (ppm) | (Mass %) |
| Comparative Example 1 | 95 | 4 | 1 | 1900 | 138 | 59 | 3.26 | 3.9 | 7 | 2.4 |

From the results shown in Table 1 and Table 2, it was confirmed that the phosphor ceramics according to Examples 1 to 13 have higher thermal conductivity than the phosphor ceramic according to Comparative Example 1. The manganese content was less than 50 ppm in Example 1 and less than 10 ppm in Examples 2 to 13. In addition, it was confirmed that the content of manganese contained in the phosphor ceramic according to Example 13 was 5 ppm. It was confirmed that the content of manganese contained in the phosphor ceramic according to Comparative Example 1 was 7 ppm. The content of manganese contained in the aluminum nitride ceramic according to Reference Example 1 was confirmed to be at least less than 1 ppm. Moreover, in the phosphor ceramics according to Examples 2 to 13, it was confirmed that the content of yttrium was less than 0.1 mass %, and the content of oxygen was less than 0.1 mass %.

SEM

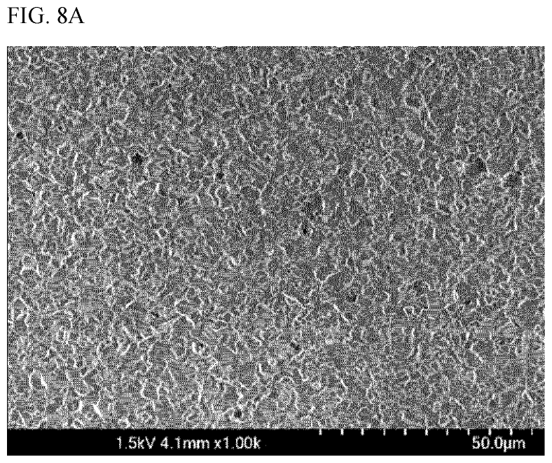

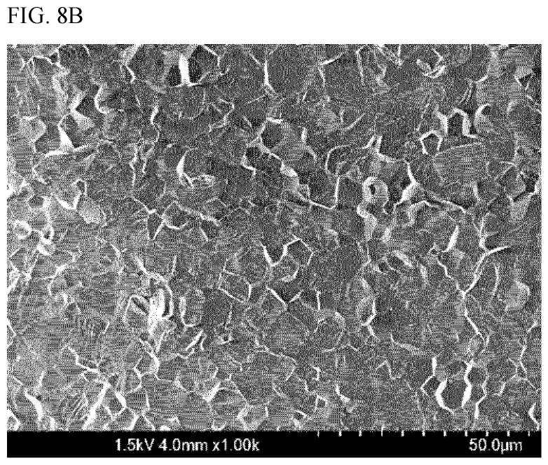

The phosphor ceramics according to Example 1 and Example 11 were observed by SEM. In the observation by SEM, a straight line was drawn in a region of 127 μm×88 μm in a cross-sectional SEM image observed at a magnification of 1000 times, the lengths from one grain boundary to another grain boundary of the AlN particles overlapping the straight line were measured, and an average value of the lengths thereof was calculated. FIG. 8A and FIG. 8B are cross-sectional SEM images used to calculate each average value. It was confirmed by SEM observation that the average value of the grain diameters of the crystal phase of Example 1 illustrated in FIG. 8A was approximately 1.9 μm. In was also confirmed by SEM observation that the average value of the grain diameters of the crystal phase of Example 11 illustrated in FIG. 8B was approximately 4.3 μm. Accordingly, it was confirmed that the particle diameter of Example 11 in which the sintered body was used as the precursor was larger.

Embodiments, examples, and the like relating to the phosphor ceramic of the present disclosure were described above, but the present disclosure may also have the following configurations.

(Aspect 1)

A method for manufacturing a phosphor ceramic, the method including:
preparing a precursor in which a base material is aluminum nitride; and
forming a phosphor ceramic by bringing the precursor into contact with a gas containing manganese.

(Aspect 2)

The method for manufacturing a phosphor ceramic according to aspect 1, wherein in the forming of the phosphor ceramic, the precursor is fired at a temperature in a range of 1600° C. to 2000° C.

(Aspect 3)

The method for manufacturing a phosphor ceramic according to aspect 1 or 2, wherein the gas containing manganese is formed by reducing manganese oxide.

(Aspect 4)

The method for manufacturing a phosphor ceramic according to aspect 3, wherein a charging amount of the manganese oxide is in a range of 0.15 g to 3.0 g per 1 g of the precursor.

(Aspect 5)

The method for manufacturing a phosphor ceramic according to any one of aspects 1 to 4, wherein the precursor is a sintered body in which a base material is aluminum nitride.

(Aspect 6)

The method for manufacturing a phosphor ceramic according to aspect 5, wherein the precursor contains oxygen, and a content of oxygen in the precursor is 0.3 mass % or less.

(Aspect 7)

A method for manufacturing a light-emitting device, the method including:
preparing a phosphor ceramic manufactured by the manufacturing method described in any one of aspects 1 to 6;
preparing an excitation light source; and
arranging the phosphor ceramic at a position irradiated by light emitted by the excitation light source.

(Aspect 8)

A phosphor ceramic containing aluminum nitride, yttrium, and manganese, wherein a content of oxygen in the phosphor ceramic is less than 2.4 mass %.

(Aspect 9)

The phosphor ceramic according to aspect 8, wherein the content of oxygen is 1 mass % or less.

(Aspect 10)

The phosphor ceramic according to aspect 8 or 9, wherein a content of manganese is 50 ppm or less.

(Aspect 11)

The phosphor ceramic according to any one of aspects 8 to 10, wherein an excitation spectrum of the phosphor ceramic has a peak in a wavelength range of 230 nm to 250 nm.

(Aspect 12)

The phosphor ceramic according to any one of aspects 8 to 11, wherein an emission spectrum of the phosphor ceramic has a peak in a wavelength range of 590 nm to 620 nm.

(Aspect 13)

A light-emitting device including:
an excitation light source; and
a phosphor ceramic described in any one of aspects 8 to 12 and arranged at a position irradiated with light emitted by the excitation light source.

1. A method for manufacturing a phosphor ceramic, the method comprising:
preparing a precursor comprising aluminum nitride; and
forming the phosphor ceramic by bringing the precursor into contact with a gas containing manganese.

2. The method for manufacturing a phosphor ceramic according to claim 1, wherein in the forming of the phosphor ceramic, the precursor is fired at a temperature in a range of 1600° C. to 2000° C.

3. The method for manufacturing a phosphor ceramic according to claim 1, wherein the gas containing manganese is formed by reducing manganese oxide.

4. The method for manufacturing a phosphor ceramic according to claim 2, wherein the gas containing manganese is formed by reducing manganese oxide.

5. The method for manufacturing a phosphor ceramic according to claim 3, wherein a charging amount of the manganese oxide is in a range of 0.15 g to 3.0 g per 1 g of the precursor.

6. The method for manufacturing a phosphor ceramic according to claim 1, wherein the precursor is a sintered body in which a base material is aluminum nitride.

7. The method for manufacturing a phosphor ceramic according to claim 4, wherein the precursor is a sintered body in which a base material is aluminum nitride.

8. The method for manufacturing a phosphor ceramic according to claim 6, wherein the precursor comprises oxygen, and
a content of oxygen in the precursor is 0.3 mass % or less.

9. The method for manufacturing a phosphor ceramic according to claim 7, wherein the precursor comprises oxygen, and
a content of oxygen in the precursor is 0.3 mass % or less.

10. A method for manufacturing a light-emitting device, the method comprising:
preparing a phosphor ceramic manufactured by the method according to claim 1;
preparing an excitation light source; and
arranging the phosphor ceramic at a position irradiated by light emitted by the excitation light source.

11. A phosphor ceramic comprising aluminum nitride, yttrium, and manganese, wherein
a content of oxygen in the phosphor ceramic is less than 2.4 mass %.

12. The phosphor ceramic according to claim 11, wherein the content of oxygen in the phosphor ceramic is 1 mass % or less.

13. The phosphor ceramic according to claim 11, wherein a content of manganese in the phosphor ceramic is 50 ppm or less.

14. The phosphor ceramic according to claim 12, wherein a content of manganese in the phosphor ceramic is 50 ppm or less.

15. The phosphor ceramic according to claim 11, wherein an excitation spectrum of the phosphor ceramic has a peak in a wavelength range of 230 nm to 250 nm.

16. The phosphor ceramic according to claim 11, wherein an emission spectrum of the phosphor ceramic has a peak in a wavelength range of 590 nm to 620 nm.

17. The phosphor ceramic according to claim 11, wherein a thermal diffusivity measured by the laser flash method at 25° C. is in a range of 60 mm²/s to 136.3 mm²/s.

18. The phosphor ceramic according to claim 11, wherein a thermal conductivity of the phosphor ceramic is in a range of 150 W/(m·K) to 260 W/(m·K).

19. A light-emitting device comprising:
an excitation light source; and
the phosphor ceramic according to claim 11 and arranged at a position irradiated with light emitted by the excitation light source.

20. The method for manufacturing a phosphor ceramic according to claim 1,
wherein aluminum nitride is a base material in the precursor.
